(19) United States
(12) Patent Application Publication
(10) Pub. No.: US 2026/0032978 A1
(43) Pub. Date: Jan. 29, 2026

(54) SEMICONDUCTOR DEVICE AND METHOD FOR FORMING A CONDUCTIVE MEMBER AND A DIELECTRIC STRUCTURE IN A TRENCH

(71) Applicant: Infineon Technologies Austria AG, Villach (AT)

(72) Inventor: Michael Hutzler, Villach (AT)

(21) Appl. No.: 19/263,690

(22) Filed: Jul. 9, 2025

(30) Foreign Application Priority Data
Jul. 26, 2024 (DE) 10 2024 121 365.5

(51) Int. Cl. H10D 64/00; H10D 30/66; H10D 64/01

(52) U.S. Cl. CPC H10D 64/117; H10D 30/668; H10D 64/01

(57) ABSTRACT

In an embodiment, a semiconductor device includes a semiconductor substrate having a first major surface, a trench extending from the first major surface into the semiconductor substrate and having a base and a side wall extending from the base to the first major surface. A conductive member is arranged in the trench and spaced apart from the side wall of the trench by a dielectric structure that is located in the trench. The dielectric structure includes a first chamber located at the base of the trench. The conductive member has a side wall having an inner surface and an outer surface. The inner surface surrounds a second chamber that is in fluid communication with the first chamber.

### BACKGROUND

Transistors used in power electronic applications may be fabricated with silicon (Si) semiconductor materials, such as Si Power MOSFETs, and Si Insulated Gate Bipolar Transistors (IGBTs), or silicon carbide (SiC). Some electrically conducting structures integrated into semiconductor devices are electrically insulated from other parts of the device to ensure reliable functioning of the semiconductor device. Examples of such conducting structures are gate electrodes and field plates, also known as field electrodes, which are insulated from the semiconductor substrate by insulation layers such as oxide layers. For example, an electrically conductive field plate may be located in a trench formed in the semiconductor substrate. The field plate is electrically insulated from the semiconductor substrate by an insulating layer, also known as a field dielectric, that lines the trench. As comparably high voltages may occur between a field plate and the semiconductor substrate during operation of the semiconductor device, the insulation layer may be thick to prevent electrical breakdown. However, a thick insulation layer occupies more space and may increase the size of the respective device.

A transistor device for power applications may be based on the charge compensation principle. In some designs, the transistor device includes an active cell field including a plurality of trenches, each including a field plate for charge compensation. US 2017/0338338 A1 describes a method for fabricating a cavity in a recess formed in a semiconductor substrate. The cavity is formed between an electrically conductive filling material and the side wall of the recess.

It is desirable to reduce the size of power semiconductor devices whilst at least maintaining if not improving the performance and reliability of the device, for example by further reducing the risk of undesirable electrical breakdown. Methods for fabricating a semiconductor device with reduced size and good performance are also desirable.

### SUMMARY

In an embodiment, a semiconductor device comprises a semiconductor substrate comprising a first major surface, a trench extending from the first major surface into the semiconductor substrate and having a base and a side wall extending from the base to the first major surface. A conductive member is arranged in the trench and spaced apart from the side wall of the trench by a dielectric structure that is located in the trench. The dielectric structure comprises a first chamber located at the base of the trench. The conductive member has a side wall having an inner surface and an outer surface. At least a part of the inner surface surrounds a second chamber that is connected with the first chamber.

In an embodiment, a method of forming an electrode and dielectric structure in a trench is provided. The method comprises forming a trench in the first major surface of a semiconductor substrate, the trench having a base and a side wall extending from the base to the first major surface, forming a first dielectric layer on the side wall and the base of the trench, forming an electrically conductive layer on the dielectric material, wherein the electrically conductive layer surrounds a gap in the trench, selectively removing at least a portion of the conductive layer that is located on the base of the trench and forming a first aperture that exposes the dielectric material on the base of the trench, and selectively removing a portion of the dielectric material through the aperture to form a first chamber at the base of the trench.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

FIG. 1 illustrates a semiconductor device comprising a conductive member and dielectric structure located in a trench.

FIG. 2A illustrates a semiconductor device comprising a field plate and dielectric structure located in a trench.

FIG. 2B illustrates a semiconductor device comprising a gate electrode and dielectric structure located in a trench.

FIGS. 3A to 3E illustrate a method for forming a conductive member and a dielectric structure in a trench.

FIGS. 4A to 4D illustrate a method for forming a conductive member and a dielectric structure in a trench.

FIGS. 5A to 5E illustrate a method for forming a conductive member and a dielectric structure in a trench.

FIGS. 6A to 6C illustrate a semiconductor device comprising a conductive member and dielectric structure located in a trench according to further embodiments.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

The Figures illustrate relative doping concentrations by indicating “−” or “+” next to the doping type “n” or “p”. For example, “n⁻” means a doping concentration which is lower than the doping concentration of an “n”-doping region while an “n⁺”-doping region has a higher doping concentration than an “n”-doping region. Doping regions of the same relative doping concentration do not necessarily have the same absolute doping concentration. For example, two different “n”-doping regions may have the same or different absolute doping concentrations.

In some embodiments, the semiconductor device is a transistor device. The transistor device may be a vertical transistor device. A vertical transistor device has a vertical drift path which is formed substantially perpendicularly to the two opposing major surfaces of the device. The transistor device may be a MOSFET (Metal Oxide Semiconductor Field Effect Transistor) device, an insulated gate bipolar transistor (IGBT) device or a Bipolar Junction Transistor (BJT).

The electrodes or terminals of the transistor device are referred to herein as source, drain and gate. As used herein, these terms also encompass the functionally equivalent terminals of other types of transistor devices, such as an insulated gate bipolar transistor (IGBT). For example, as used herein, the term “source” encompasses not only a source of a MOSFET device and of a superjunction device but also an emitter of an insulator gate bipolar transistor (IGBT) device and an emitter of a Bipolar Junction Transistor (BJT) device, the term “drain” encompasses not only a drain of a MOSFET device or of a superjunction device but also a collector of an insulator gate bipolar transistor (IGBT) device and a collector of a BJT device, and the term “gate” encompasses not only a gate of a MOSFET device or of a superjunction device but also a gate of an insulator gate bipolar transistor (IGBT) device and a base of a BJT device.

According to the present disclosure, a semiconductor device is provided which has a cavity in a trench. The cavity is located between a conductive member, such as a field plate or an electrode, e.g. a gate electrode, and the semiconductor substrate. The cavity may be located at the base of the trench. The cavity is filled with one or more gases or a vacuum so as to have a lower relative dielectric constant than silicon dioxide. The semiconductor device may be a transistor device, such as a trench MOSFET.

A trench for a field plate may be lined with a dielectric material for electrical insulation. Silicon dioxide may be used as the dielectric material, for example for silicon-based devices, such as a MOSFET. Silicon dioxide as a dielectric for field plate compensation has a relative dielectric constant of 3.9 and a bandgap of roughly 9 eV. For vacuum, these parameters are 1.0 and >20 eV respectively. Replacing silicon dioxide by vacuum in compensation devices may have at least the effect of enabling a reduction of dielectric thickness of the compensation element that achieves a similar compensation effect. This leads to a reduction of device-pitch and a reduction in the parameter Ron X A, where Ron is on-state resistance and A is area. Furthermore, the larger “bandgap” of a vacuum or gas compared to silicon dioxide raises the critical electrical field until dielectric breakdown occurs. This enables larger electrical fields across the dielectric and higher epitaxy doping, e.g. of the drift region, which also results in a reduction in Ron X A.

Methods for forming such a structure are also provided. The conductive member, e.g. field plate is hollow and is used to inject chemicals into the lower part of the field dielectric in the trench in order to etch and remove this field dielectric and create a buried, enclosed and sealed cavity. The cavity may be gas filled and/or comprise a vacuum. The hollow field plate may have a tubular form and is anchored to the mesa via the non-etched parts of the field dielectric such that mechanical and electrostatic stability is provided.

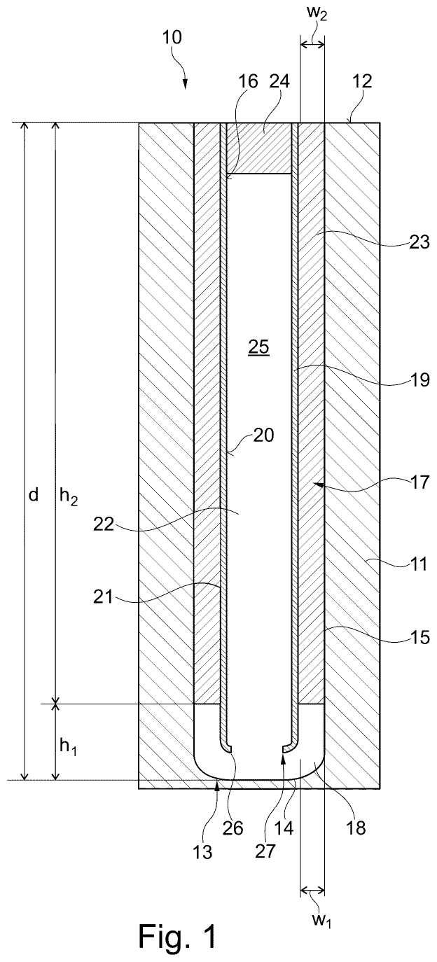

FIG. 1 illustrates a cross-sectional view of a semiconductor device 10 according to an embodiment. The semiconductor device 10 comprises a semiconductor substrate 11 comprising a first major surface 12. A trench 13 is located in the semiconductor substrate 11 and extends from the first major surface 12 into the semiconductor substrate 11. The trench 13 has a base 14 and sidewall 15 extending from the base 14 to the first major surface 12. A conductive member 16 is arranged in the trench 13 and is spaced apart from the sidewall 15 of the trench 13 by a dielectric structure 17. The dielectric structure 17 comprises a first chamber 18 which is located at the base 14 of the trench 13. The conductive member 16 has a sidewall 19 having an inner surface 20 and an outer surface 21. The inner surface 20 surrounds a second chamber 22 which conjoins or connects with the first chamber 18 to form a single empty space. The second chamber 22 is in fluid communication with the first chamber 18. The term “in fluid communication” means that the first chamber 18 and second chamber 22 are connected such that a fluid, e.g. a liquid or a gas, would be able to flow between the first chamber 18 and second chamber 22. The conductive member 16 is hollow and has a tubular form. The first chamber 18 and second chamber 22 are empty and comprise a gaseous atmosphere and/or a vacuum.

The first chamber 18 is positioned under the conductive member 16 and also extends between the lower portion of the outer surface 21 of the conductive member 16 and a lower portion of the sidewall 15 of the trench 13. A lower portion of the sidewall 19 of the conductive member 16 protrudes into the first chamber 18.

The dielectric structure 17 further includes a first dielectric material 23, which may comprise silicon oxide for example, which extends between an upper portion of the sidewall 15 of the trench 13 and an upper portion of the outer surface 21 of the sidewall 19 of the conductive member 16. This first dielectric material 23 secures the conductive member 16 to the sidewall 15 of the trench and secures the position of the conductive member 16 within the trench 13. The lower portion of the sidewall 19 of the conductive member 16 is located within the first chamber 18 so that the outer surface 21 is in direct contact with the first chamber 18. In some embodiments, the lower portion of the side wall 19 of the conductive member is exposed from, and not in contact with, the first dielectric material 23.

The first dielectric material 23 extends from the first chamber 18 to the first major surface 12 so that the lower surface of the first dielectric material 23 provides the upper surface of the first chamber 18. The portion of the first chamber 18 located between the outer surface 21 of the side wall 19 of the conductive member 16 and the side wall 15 of the trench 13 has a height h1 as measured from the base 14 of the trench 13. The portion of the sidewall 15 of the trench 13 that is in contact with the first dielectric material 23 has a height h2. The trench 13 has a depth d, the depth being the distance of the base 14 from the first major surface 12. Consequently, the sum of the height h1 of the first chamber 18 and the height h2 of the dielectric material 23 located on the side wall 15 of the trench 13 is equal to the depth d of the trench 13, i.e. d=h1+h2.

In some embodiments, ratio of h1/h2 may lie in the range of 1 to 9 to 1 to 1. This proportion of the height of the conductive member 16 that is attached to the side wall 15 of the trench 13 by the first dielectric material 23 is sufficient to improve the mechanical stability of the conductive member 16 and, therefore, its electrical stability.

In some embodiments, the trench 13 is an elongate stripe-like trench. An elongate trench has a length which extends in a plane parallel to the first major surface 12. The length is greater than its depth, d, in the substrate 11, that is its depth perpendicular to the first major surface 12. The depth is greater than a width of the trench in a plane parallel to the first major surface. In some embodiments, the semiconductor device 10 comprises a plurality of elongate stripe-like trenches 13 that extend substantially parallel to one another. An elongate strip-like trench 13 may be substantially rectangular in plan view so that the side wall 15 of the trench 13 comprises four side wall sections, whereby adjoining side wall sections are arranged substantially perpendicularly to one another.

In some embodiments, the trench 13 is a columnar trench. A columnar trench 13 may also be called a needle trench or a specular trench. A columnar trench 13 has a small or narrow circumference or width in proportion to its height/depth in the substrate 11, that is its height/depth perpendicular to the first major surface 12. A columnar trench 13 may have an octagonal, circular, square, hexagonal and shape in plan view. The columnar trenches 13 and consequently the conductive member 16 positioned in the trench 13 may be arranged in a regular square grid array of rows and columns, or an offset rows or a hexagonal array, for example.

If the columnar trench 13 is circular in plan view it has a single continuous side wall 15. If the columnar trench 13 has a square or hexagonal or octagonal shape in plan view, the side wall 15 comprises four or six or eight side wall sections, respectively, that extend at an angle to one another.

The conductive member 16 can be considered to be hollow and have a generally tubular shape, since the side wall 19 of the conductive member surrounds the second chamber which is a void or empty space. The shape in plan view of the columnar trench 13 may be the same as, or different from, the shape in plan view of the conductive member 16. The outer contour and lateral shape of the conductive member 16 may correspond to the lateral shape of the trench 13. For example, if the trench 13 is a circular columnar trench, the conductive member 16 may have a circular lateral form. In this embodiment, the conductive member 16 may have the form of a substantially cylindrical tube or pipe. In another embodiment, the columnar trench 13 may be laterally hexagonal in which case the conductive member 16 may also have a lateral hexagonal form. In embodiments in which the trench 13 is an elongated strip-like trench, the conductive member 16 may have a sidewall 19 which has an elongated rectangular lateral form, for example.

The shape in plan view of the columnar trench 13 may be different from the shape in plan view of the conductive member 16. For example, a circular conductive member 16 may be arranged in a hexagonal trench.

The cross-sectional view of FIG. 1 applies for both an elongate strip-like trench whose length extends into the plane of the drawing and for a columnar trench.

The first chamber 18 and the second chamber 22 are empty or are at least partially free of dielectric material in the solid state. In some embodiments, the second chamber 22 is covered at the first major surface 12 by a second dielectric material 24. The second dielectric material 24 extends between the inner surfaces 20 of the second chamber 22 and seals the upper portion of the second chamber 22 thus forming a cavity 25 which is made up of the first chamber 18 and second chamber 22. The cavity 25 is an enclosed cavity in the form of a sealed empty space or sealed and enclosed void which may comprise a vacuum and/or a gas or gases, for example the process environment present when the cavity was sealed. The second dielectric material 24 may be located within the upper portion of the trench 13 only or may further extend over the first major surface 12.

This cavity 25 is located in the trench 13 and is bounded by the lower surface of the second dielectric material 24, the inner surface 20 of the sidewall 19 of the conductive member 16, the outer surface 21 of the sidewall 19 of the conductive member 16 that is located within the first chamber 18, the lower surface of the first dielectric material 23 and the lower portion of the sidewall 15 and base 14 of the trench 13.

Since the cavity 25 formed from the sealed first and second chambers 18, 22 comprises a vacuum or gas, its relative dielectric constant is lower than that provided by the solid state first dielectric material 23, e.g. silicon dioxide. This is useful as the electric field is generally higher at the base of the conductive member 16. This arrangement of the first chamber 18 of the dielectric structure 17 between the conductive member 16 and the semiconductor substrate 11 provides improved electrical isolation. Thus, dielectric breakdown can be better avoided. Additionally, the thickness of the dielectric structure 17 may be reduced while maintaining a breakdown voltage so that the area occupied is reduced. Thus, in a transistor device, the parameter Ron X A can be reduced. The introduction of the vacuum/gas cavity 25 at the bottom of the trench 13 enables a reduction of dielectric thickness, while still providing sufficient electrical dielectric blocking capability. This reduced dielectric thickness may translate into a reduced device pitch or reduced lateral dimension of the device.

In some embodiments, such as that illustrated in FIG. 1, the thickness of the first dielectric material 23 is substantially uniform. In FIG. 1, the spacing between the outer surface 21 of the sidewall 19 of the conductive member 16 and the sidewall 15 of the trench 13 is substantially uniform throughout the depth of the trench, that is from the base 14 to the first major surface 12. Thus, the width w1 of the first chamber 18 between the outer surface 21 of the sidewall 19 of the conductive member 16 and the sidewall 15 of the trench 13 is substantially the same as the width w2 of the first dielectric material 23 that is located on the upper portion of the sidewall 15 the trench 13.

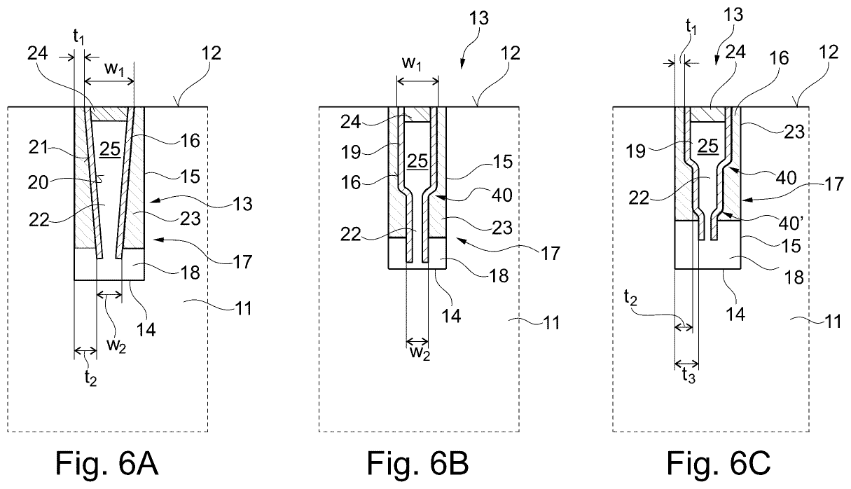

In other embodiments, such as those illustrated in FIGS. 6A to 6C, the thickness of the dielectric structure 17 and the dielectric material 23 varies along the depth of the trench.

The first dielectric material 23 may be formed of silicon oxide, e.g. SiOx or SiO₂, or silicon nitride. The second dielectric material 24 may also be formed of silicon oxide, e.g. SiOx or SiO₂. In some embodiments, the first dielectric material 23 may have two or more sublayers. For example, the first dielectric material 23 may include a first sublayer of silicon nitride and a second sublayer of silicon oxide located on the first sublayer. Alternatively, the first dielectric material 23 may comprise two sublayers of silicon oxide which are formed by differing methods, for example a deposited silicon oxide layer and a thermally grown silicon oxide layer. In an embodiment, the first dielectric material 23 and the second dielectric material 24 comprise silicon oxide. The conductive member 16 is formed of an electrically conductive material and may be formed of polysilicon or a metal, e.g. TiN or W. The conductive member 16 may also comprise two or more sublayers.

The semiconductor substrate 11 may be formed of silicon, for example a single crystal silicon wafer or monocrystalline silicon or SiC, for example a monocrystalline silicon layer, e.g. an epitaxial silicon layer (epi layer) which is formed on the base substrate.

In some embodiments, for example, that of FIG. 1, the conductive member 16 comprises a base 26 which protrudes inwardly from, and extends between, the opposing portions of the inner surface 20 of the sidewall 19. The base 26 includes an aperture 27 which extends through the thickness of the conductive material and enables the second chamber 22, which is bounded by the inner surface 20 of the sidewall 19 of the conductive member 16, to be connected to with the first chamber 18 which is positioned on the opposing side of the base 26 and sidewall 19 and which is in contact with the outer surface 21 of the sidewall 19. The aperture 27 is bounded by a peripheral portion of the base 26, e.g. a peripheral ring. The peripheral ring is located in the first chamber 18 and may be entirely exposed from the first dielectric material 23. In other embodiments, such as that shown in FIG. 6A, the base 26 may be absent such that the distal end face of the conductive member 16 is formed by the end face of the sidewall 19.

The trench structure shown in FIG. 1 may be used to provide various functions in a semiconductor device.

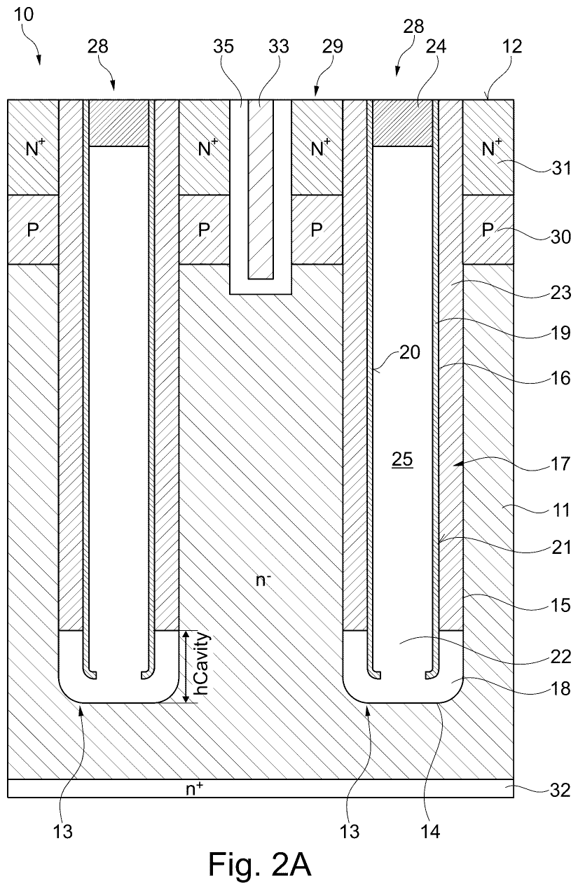

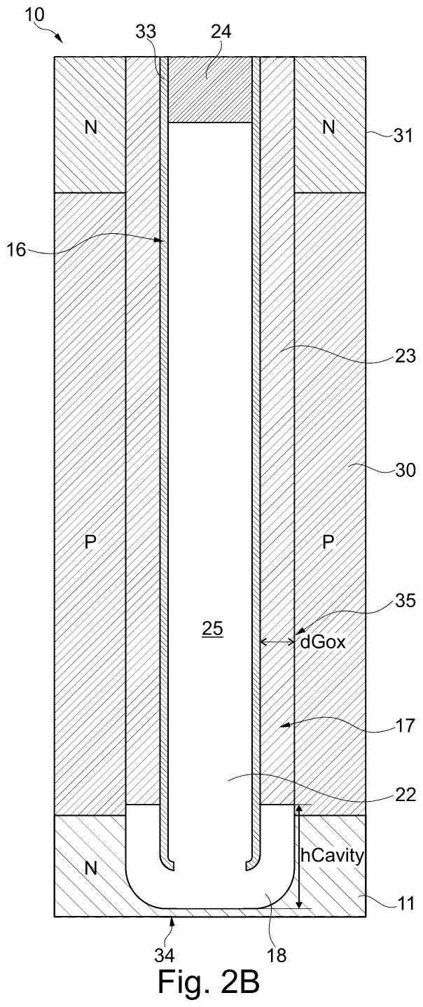

FIG. 2A illustrates a cross-sectional view of a semiconductor device 10 according to an embodiment in which this structure including the conductive member 16 and dielectric structure 17 in the trench 13 is used to provide a field plate for a transistor device, e.g. a MOSFET. The dielectric structure 17 electrically isolates the field plate 16 from the semiconductor substrate 11. The conductive member 16 provides a hollow field plate 16 which forms part of the charge compensation structure of the transistor device 10. The transistor device 10 includes a plurality of transistor cells 28 coupled in parallel. Each transistor cell 28 includes a trench 13 with a hollow field plate 16 and the dielectric structure 17 including the cavity 25 and a mesa 29 that is located adjacent the trench 13 and that extends between adjacent ones of the trenches 13.

The semiconductor substrate 11 may be formed of silicon, for example a single crystal silicon wafer or monocrystalline silicon, for example a monocrystalline silicon layer, e.g. an epitaxial silicon layer (epi layer) which is formed on the base substrate. Alternatively, the semiconductor substrate 11 may be formed of SiC, e.g. monocrystalline SiC.

The semiconductor substrate 11 comprises a first conductivity type, for example n-type, and provides the drift region of the transistor device 10. The transistor device 10 further comprises a body region 30 of the second conductivity type which opposes the first conductivity type, p type in the case that the first conductivity type is n-type, formed in the semiconductor substrate 11. The body region 30 forms a pn junction with the drift region. The transistor device 10 further comprises a source region 31 which is located on or in the body region 30 and which comprises the first conductivity type. The semiconductor substrate 11 further comprises a drain region 32 of the first conductivity type which is located at the second major surface 26 of the semiconductor substrate 11 which opposes the first major surface 12. The source region 31 and the drain region 32 are more highly doped than the drift region. The transistor device 10 further includes a gate electrode 33 which is located in a gate trench 34 which is lined with a gate dielectric 35. The gate trench 34 is positioned in the mesa 29 and laterally spaced apart from the trench 13. The transistor device 10 is a vertical transistor device, e.g. a power MOSFET.

FIG. 2B illustrates a cross-sectional view of a semiconductor device 10 and the use of the structure of FIG. 1 in a trench gate structure of a transistor device 30. In this embodiment, the conductive member 16 provides the gate electrode 33 and the first dielectric structure 17 comprising the first dielectric material 23 and the first chamber 18 provides the gate dielectric that is located in the gate trench 34. The gate electrode 33 may be formed of polysilicon or a metal and the first dielectric material 23 may be formed of silicon oxide.

The gate trench 24 differs from a trench for a field plate in its dimensions. For example, the base of the gate trench 34 is located laterally adjacent the body region 30, whereas the base 14 of the trench 13 for the field plate 16 is deeper and located in the drift region provided by the semiconductor substate 11.

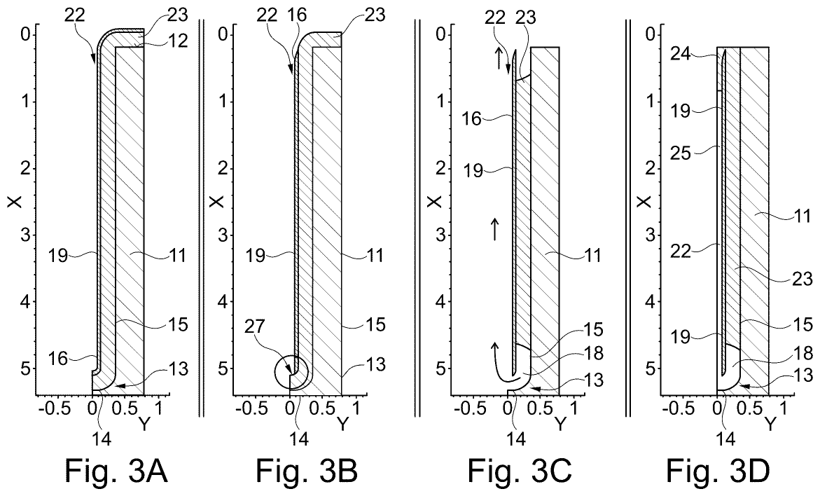

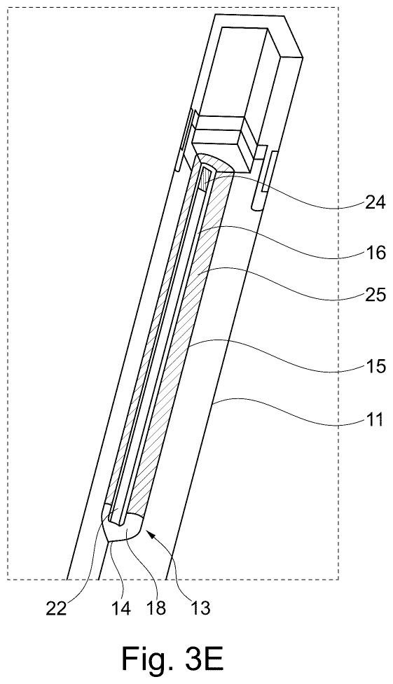

The dielectric structure 17 and conductive member 16 may be formed in the trench 13 using various methods. A method, which may be used for forming the dielectric structure 17 and conductive member 16 in the trench 13, will now be described with reference to FIGS. 3A to 3E. The method is illustrated by referring to a single trench 13. However, the device may include a plurality of trenches and the process is carried out for each of these trenches using the same process.

FIG. 3A illustrates a cross-sectional view of a trench 13 formed in the first major surface 12 of the semiconductor substrate 11. The trench 13 has a base 14 and a side wall 15 which extends from the base 14 to the first major surface 12. A first dielectric layer 23 is formed which lines the sidewall 15 and base 14 of the trench 13 and also extends over the first major surface 12 of the semiconductor substrate 11. The first dielectric layer 23 may be thermally grown or formed by a TEOS deposition process, for example. The first dielectric layer 23 has a substantially uniform thickness. An electrically conductive layer 16 is deposited over the first dielectric layer 23 and extends over the first major surface 12, sidewall 15 and base 14 of the trench 13 and is in direct contact with the first dielectric layer 23. The electrically conductive layer 16 has a thickness such that it surrounds a gap or unoccupied region at the centre of the trench 13 which forms a second chamber 22. For example, the electrically conductive layer 16 may be formed of polysilicon and have a thickness of 50 nm and the first dielectric layer 23 may comprise silicon oxide.

Referring to FIG. 3B, at least a portion of the conductive layer 16 which is located on the base 14 of the trench 13 is removed to form an aperture 27 in the conductive layer 16 which exposes a portion of the underlying first dielectric layer 23 which is located on the base 14 of the trench 13. In some embodiments, this removal process may also remove the portion of the conductive layer 16 which is located on the first major surface 12. Thus, discrete separate conductive members 16 are formed, one in each trench 13. The conductive layer 16 is selectively removed over the material of the first dielectric layer 23. For example, the conductive layer 16 may be removed by selective etching. In selective removal such as selective etching, a selectivity of one material over another material is at least 100:1. In an embodiment, the conductive layer 16 is selectively removed by anisotropic etching, i.e. an etching process, in which the etch rate, i.e. removal rate, is higher on lateral, e.g. horizontal surfaces, than on vertical surfaces.

Referring to FIG. 3C, a portion of the first dielectric layer 23 is removed through the aperture 27 formed in the conductive layer 16 and through the second chamber 22 which is open at the first major surface 12, as shown by the arrows in FIG. 3C, and a first chamber 18 is formed at the base of the trench 13. The portion of the first dielectric layer 23 is selectively removed over the material of the conductive layer 16. For example, isotropic etching, e.g. wet etching, or anisotropic etching may be used. The etch chemicals are directed by way of the hollow conductive member 23 to the base of the trench 23 to the exposed region of the first dielectric material 23 thus enabling the removal of the first dielectric material 23 that is located at the bottom of the trench without these etch materials coming into contact with the remainder of the first dielectric material 23 that is located between the intermediate section of the side wall 15 of the trench and the outer surface of the conductive member 16. The first chamber 18 is conjoined with and in fluid communication with the second chamber 22 as, for example, the etch chemicals are able to move between the first chamber 18 and the second chamber 22.

In some embodiments, a portion of the first dielectric layer 23 which is located adjacent the side wall 15 of the trench 13 is also removed so that the outer surface 21 of the lower portion of the conductive layer 16 is uncovered from the first dielectric layer 23 and the exposed lower portion of the side wall 19 of the conductive layer 16 extends into an empty first chamber 18. The etch time may be selected in order to control the extent of the removal of the first dielectric material 23. In some embodiments, an uppermost portion of the first dielectric layer 23 which is located adjacent to the first major surface 12 is also removed during this process such that the upper most portion of the conductive layer 16 is also entirely uncovered by the first dielectric layer 23.

Since only a portion of the first dielectric layer 23 is removed through the aperture 27 from the bottom of the trench 13, in particular the regions of the first dielectric layer 23 which are adjacent to the aperture 27 are removed, a portion of the first dielectric layer 23 remains and secures the conductive layer 16 to the sidewall 15 of the trench 13. The height of this remaining material is sufficient to provide support for the lowermost and in some cases also the uppermost portion of the sidewall 19 of the conductive layer 16 which is uncovered from the first dielectric layer 23. The lowermost portion of the conductive layer 16 is in contact with and entirely surrounded by the first chamber 18 and second chamber 22.

Referring to FIG. 3D, in some embodiments, a second dielectric layer 24 is formed on the first major surface 12 which fills the uppermost portion of the second chamber 22 and which seals the gap thus forming an enclosed cavity which comprises the first chamber 18 and the second chamber 22. In some embodiments, the second dielectric layer 24 is formed over the first major surface 12 and fills the uppermost portion of the trench 13. The second dielectric layer may be formed of silicon oxide and deposited using HDP (High Density Plasma) deposition or PECVD (Plasma Enhanced Chemical Vapour Deposition), for example. Subsequently, a planarisation process is carried out to remove the second dielectric layer 24 from the first major surface 12. In some embodiments, some of the second dielectric 24 layer remains on the first major surface. This remaining portion of the second dielectric layer 24 can be used as a hard mask in later manufacturing processes, for example as a hard mask for forming the gate trench and gate structure.

The conductive layer 16 forms a conductive member with a side wall 19 that surrounds an empty space in the form of the second chamber 22. The conductive member 16 has a tubular form. FIG. 3E illustrates a perspective view of the conductive member 16 formed in the trench 13 in which its cylindrical tubular shape can be seen.

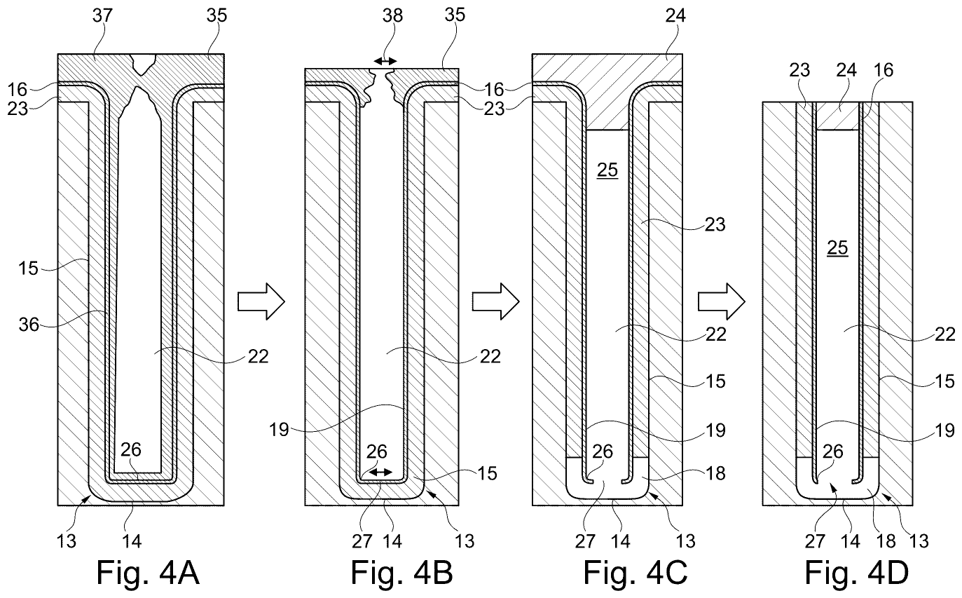

FIGS. 4A to 4D illustrate a method according to another embodiment for fabricating a conductive member and dielectric structure in a trench, which may be used to form the structure illustrated in FIGS. 1 and 2A-2B. For example, the method may be used to form the first aperture 27 in the base 26 of the conductive layer 16 located on the base 14 of the trench 13.

Referring to FIG. 4A, after forming the trench 13 in the first major surface 12 and lining the trench with the first dielectric layer 23 and the electrically conductive layer 16 as described with reference to FIG. 3A, a third dielectric layer 35 is deposited using a non-conformal process. The third dielectric layer 35 has a first portion 36 that extends over the conductive layer 16 located on the sidewall 15 and base 14 of the trench 13 and has a first thickness on these surfaces. The third dielectric layer 35 is also formed over the conductive layer 16 that is located on the first major surface 12 and this upper second portion 37 of the third dielectric 35 has a greater thickness than the thickness of the first portion 36 located within the trench 13. The third dielectric layer 35 extends over and covers the second chamber 22 formed at the centre of the trench 13.

Referring to FIG. 4B, a central portion of the upper portion 37 of the third dielectric layer 35 is removed to form a second aperture 38 and the thinner portion 36 of the third dielectric layer 35 is selectively removed from the sidewall 15 and base 14 of the trench 13, e.g. by selective etching, thus exposing the conductive layer 16. Then the conductive layer 16 positioned on the base 14 of the trench 13 is selectively removed, e.g. selectively etched, using the second aperture 38 in the third dielectric layer 35 as a mask to form the first aperture 27 which exposes the first dielectric layer 23 located on the base 14 of the trench 13.

Referring to FIG. 4C, the method continues by selectively removing a portion of the first dielectric layer 23 through the aperture 27, e.g. by isotropic etching, and forming the first chamber 18. The second dielectric layer 24 is deposited on the first major surface 12 so as to cover the second chamber 22 and provide a sealed cavity 25 in the trench 13 comprising the first chamber 18 the second chamber 22. Then a planarisation process carried out to form planarised surface shown in FIG. 4D.

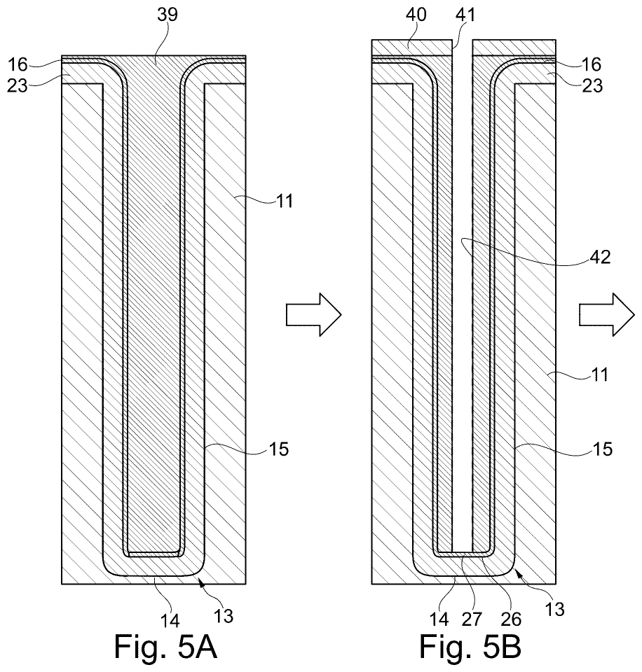

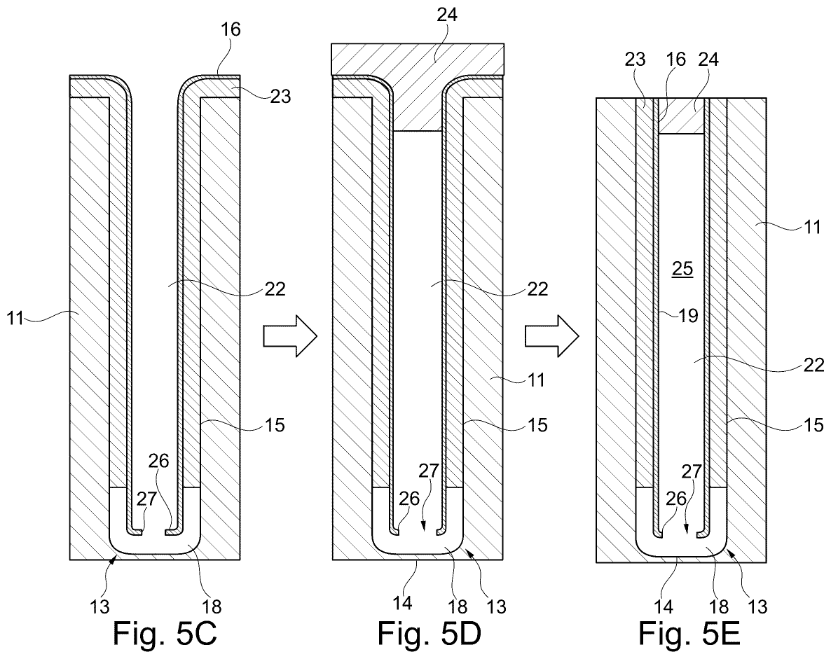

FIGS. 5A to 5E illustrate a method according to another embodiment, which may be used to form the dielectric structure 17 and conductive member 16 in the trench 13. Referring to FIG. 5A, after forming the trench 13, the first dielectric layer 23 and the electrically conductive layer 16 in the trench 13 as described with reference to FIGS. 3A to 3E, the second chamber 22, which is bounded by the conductive layer 16, is entirely filled with a fourth dielectric layer 39. Referring to FIG. 5B, a mask 40 is formed on the first major surface 12 and structured to include an opening 41 which exposes a portion of the fourth dielectric layer 39, in particular, a central portion. The mask 40 may be formed of photoresist and photolithographically structured to form the opening 41.

This mask 40 is then used to remove a portion of the fourth dielectric layer 39 to form an opening 42 which extends through the fourth dielectric layer 39 and which exposes a portion of the conductive layer 16 which is located on the base 14 of the trench 13. Isotropic or anisotropic etching may be used to form the opening 42. The mask 40 in combination with the opening 42 formed in the remaining lining provided by the fourth dielectric layer 39 provides a mask for selectively removing the exposed portion of the conductive layer 16 by, for example, anisotropic etching and forming the aperture 27 which exposes the underlying first dielectric layer 23.

The first dielectric layer 23 is removed from the bottom portion of the trench 13 through the aperture 27, for example by isotropic etching, so as to form the first chamber 18 as in the embodiments described with reference to FIGS. 3A-3E and 4A-4D. The fourth dielectric layer 39 may be removed from the trench 13 in the same process or subsequently. The mask 40 is also removed as shown in FIG. 5C. The method then continues as described reference to FIGS. 3A-3E and 4A-4D. Referring to FIG. 5D, the second dielectric layer 24 is applied to the first major surface and covers and seals the second chamber 22 to form the cavity 25 and a planarisation process is then carried out to remove the second dielectric layer 24 from the first major surface 12 as shown in FIG. 5E.

In some embodiments, the spacing between the outer surface 21 of the conductive member 16 and the sidewall 15 of the trench 13 is greater in a first portion of the trench 13 than in a second portion of the trench 13. In other words, the dielectric structure 17 has a nonuniform width.

FIGS. 6A to 6C illustrate cross-sectional views of a trench 13 with a dielectric structure 17 that has a non-uniform width on the side wall 15 of the trench 13. These forms of the dielectric structure may be used in place of the uniform thickness of the dielectric structure 17 of the semiconductive devices 10 illustrated in FIGS. 1 to 5E.

Referring to FIGS. 6A to 6C, the dielectric structure 17 in the trench 13 has a first thickness t1 on the side wall 15 in an upper portion of the trench 13 and a second thickness t2 on the side wall 15 in the lower portion of the trench 13. The second thickness t2 of the dielectric structure 17 in a lower portion of trench 13 is greater than the thickness t1 in the upper portion of the trench 13. The conductive member 16 has a larger outer width w1 in the upper portion of the trench 13 than its width w2 in the lower portion of the trench 13.

In some embodiments, the thickness t₁≤1.15 times the thickness t₂ and consequently the thickness t₁ is greater than typical process variations. In some embodiments, the difference is greater so that t₁≤1.2 t₂ or t₁≤1.5 t₂. In some embodiments, the difference is greater so that t₁≤3 t₂ or t₁≤4 t₂.

Referring to FIG. 6A, the conductive member 16 may have a tapering structure such that its width decreases from the top of the trench 13 towards the base 14 of the trench 13. The dielectric structure 17 has the opposite structure such that the thickness of the first dielectric layer 23 on the side wall 15 continuously increases in a direction from the first major surface 12 towards the base 14 of the trench 13. The first dielectric layer 23 has a thickness t1 on the side wall 15 at the first major surface 12 and decreases continuously to a thickness t2 on the side wall 15, whereby t1<t2. The first chamber 18 may also have an increasing width between the outer surface 21 of the side wall 19 of the conductive member 16 and the side wall 15 of the trench 13. The conductive member 16 can be considered to have a funnel shape.

Referring to FIG. 6B, in some embodiments, the first dielectric layer 23 of the dielectric structure 17 comprises an abrupt transition from the first to the second thickness that forms a step 40 so that the first dielectric layer 23 can be considered to have a stepped shape. In some embodiments, the first dielectric layer has the smaller thickness t1 over a first height h1 of the trench 13 in the upper portion and the larger thickness t2 over a second height h2 of the trench 13 in the lower portion.

The conductive member 16 may also have an abrupt transition between a larger outer width w1 in the upper portion of the trench 13 and a smaller outer width w2 towards the lower portion of the trench 13. The conductive member can be considered to have a step in its side wall 19 corresponding to the step 40 formed in the first dielectric layer 23. The conductive member 16 can be considered to have a T-shape in cross-section.

Referring to FIG. 6C, in an embodiment, the conductive member 16 and the dielectric structure 17 may also have more than one step 40. FIG. 6C illustrates an embodiment in which the conductive member 16 has two steps 40, 40′ such the dielectric structure 17 has three different thicknesses between the outer surface 21 of the side wall 19 of the conductive member 16 and the side wall 15 of the trench 13. The thickness increases stepwise incrementally from the first major surface 12 towards the base 14 of the columnar trench 13. In the upper portion of the side wall 15, the dielectric structure 17 has a thickness t1, in the middle portion a thickness t2 and in the third portion a thickness t3, whereby t1<t2<t3. The side face of the conductive member 16 has two steps 40, 40′ such it has three different widths and such that the outer width of the conductive member 16 decreases stepwise from the first major surface 12 towards the base 14 of the columnar trench 13.

According to the invention, a cavity is provided in the trench between the field plate and the semiconductor substrate. The cavity is filled with one or more gases and/or a vacuum so as to have a higher dielectric breakdown strength than a dielectric material such as silicon dioxide. The cavity may be located at the base of the trench. A hollow field plate is used to inject, e.g. direct, a wet etch into the lower part of the field dielectric for etching purposes so as to remove a portion of the field dielectric and creating a buried enclosed and sealed cavity at the base of the trench which may be gas filled and/or comprise a vacuum. The hollow field plate is anchored to the mesa via the non-etched parts of the field dielectric such that mechanical and electrostatic stability is provided. This structure may be fabricated using various processes.

In an embodiment, a self-aligned process is used to form the cavity in the trench. After field dielectric formation that lines the trench and extends onto the surface of the semiconductor substrate adjacent to the trench, i.e. on the mesa, a thin conductive liner, e.g. 50 nm polysilicon, is conformally deposited. The deposited thickness is chosen such that the trench is not fully closed. The liner is anisotropically etched, removing the liner from the field dielectric on the surface of the semiconductor substrate and from trench bottom, however not from the trench sidewalls. Thus, a tubular conductive member is formed in the trench that has a hollow chamber that extends from the field dielectric located on the bottom of the trench and the first surface of the substrate. Then, an isotropic etchant, e.g. wet chemistry is applied, which attacks the field dielectric at the trench bottom through the hollow field plate. Also, the exposed mesa oxide is etched. The etchant is neither etching the liner nor silicon. In other words, the field oxide is selectively removed by the isotropic wet etch. The etching time is chosen such that the cavity forms the desired transition height to the field dielectric. The hollow liner is anchored to the trench sidewall via the remaining field dielectric. In the lower part of the trench, the liner is not anchored, however the exposed part can be kept small. Furthermore, a hollow tube generally has a higher bending strength than a solid rod. The hollow liner which formed the hollow field plate is closed and the cavity sealed by e.g. a PECVD or HDP deposition of a dielectric. This dielectric may be used as a hard mask e.g. as a hard mask for forming the gate structure, e.g. gate trench.

In a further self-aligned embodiment, after depositing the conductive liner, a highly non-conformal dielectric is deposited. This non-conformal dielectric covers the open upper end of the hollow liner and also, forms a large void within the hollow liner. A short wet etch is used to open the dielectric at the top of the hollow liner to form a small top opening or aperture. Next, the liner is anisotropically etched. This may comprise an oxide step breaking through remaining oxide at the trench bottom as well as the liner etch to expose the bottom field dielectric. The dielectric at the top acts as a hard mask for this etch step and defines the opening at the trench bottom. The isotropic field dielectric etch is applied and etches the non-conformal dielectric on at the top, e.g. at the top of the hollow liner as well as etches away the field dielectric at the base of the trench to form an empty chamber. The hollow liner is closed as described above. A planarization process down to mesa level is applied. The planarization can also stop within the field dielectric such that the remaining layer can be used as hard mask, for example for forming the gate structure.

In an embodiment, an aligned method is used. After depositing the conductive liner, a highly conformal dielectric is deposited. This covers and closes the open upper end of the hollow liner, which may be void free. A CMP (Chemical Mechanical Polishing) process stopping on the liner material is used for planarization. A resist mask is applied, with an opening centered on the trench. An oxide etch (isotropic or anisotropic) is applied, removing the oxide from top of the hollow liner down to the bottom. An anisotropic liner etch is used to expose the bottom field dielectric. During this step, the liner on the mesa top is protected by resist. The resist is removed. The cavity is etched by providing etchant through the now hollow liner. In this case, the field dielectric on top of the mesa and in the top sidewall sections is not etched as it is protected by liner material. The hollow liner is closed with the method described above. A planarization is applied, maybe leaving behind a part of the original field dielectric thickness, which again can be used as a hard mask, e.g. for forming the gate. Any kind of field dielectric stepping or tapering executed before the liner, is enabled and preserved in this embodiment.

In an embodiment, the concepts described above are applied to a gate trench. The gate electrode is, therefore, hollow and comprises a side wall laterally surrounding a second chamber. A cavity is formed with a height hCavity at the base of the gate trench under the gate electrode which has a width dGox between the outer surface of the gate electrode and the side wall of the trench. The width of thickness dGox may correspond to the width or thickness of the gate dielectric, e.g. silicon dioxide. Due to the reduced dielectric constant provided by the cavity, Qgd may be reduced. Bulk hot carrier injection, typically occurring into the lower parts of the gate dielectric may be reduced and induced electrical effects like VGSTH drift may be reduced. The electrical function in regions above the cavity may not be affected.

To summarise, a trench MOSFET structure with a hollow field plate is used to inject chemicals into the lower part of the field dielectric for etching and creating a buried enclosed and sealed cavity which may be gas filled and/or comprise a vacuum. The resulting hollow field plate is anchored to the mesa via the non-etched parts of the field dielectric such that mechanical and electrostatic stability is provided.

Although the present disclosure is not so limited, the following numbered examples demonstrate one or more aspects of the disclosure.

### EXAMPLES

1. A semiconductor device, comprising:
a semiconductor substrate comprising a first major surface,
a trench extending from the first major surface into the semiconductor substrate and having a base and a side wall extending from the base to the first major surface;
a conductive member arranged in the trench and spaced apart from the side wall of the trench by a dielectric structure that is located in the trench, wherein the dielectric structure comprises a first chamber located at the base of the trench,
wherein the conductive member has a side wall having an inner surface and an outer surface, wherein the inner surface surrounds a second chamber that is in fluid communication with the first chamber.

2. The semiconductor device according to example 1, wherein the first chamber is positioned under the conductive member and between a lower portion of the outer surface of the side wall of the conductive member and a lower portion of the side wall of the trench.

3. The semiconductor device according to example 1 or example 2, wherein a lower portion of the side wall of the conductive member protrudes into the first chamber.

4. The semiconductor device according to any one of examples 1 to 3, wherein the conductive member further comprises a base, wherein an aperture extends through the base.

5. The semiconductor device according to any one of examples 1 to 4, wherein the dielectric structure further comprises a first dielectric material extending between an upper portion of the side wall of the trench and an upper portion of the outer surface of the side wall of the conductive member.

6. The semiconductor device according to example 5, wherein the first dielectric material extends from the first chamber to the first major surface.

7. The semiconductor device according to example 5 or examples 8, wherein the first chamber has a height h1, the portion of the side wall of the trench that is in contact with the dielectric material has a height h2 and the trench has a depth d, wherein d=h1+h2.

8. The semiconductor device according to any one of examples 1 to 7, wherein the second chamber is covered at the first major surface by a second dielectric material such that the first and second chambers form a cavity within the trench.

9. The semiconductor device according to any one of examples 1 to 8, wherein the first dielectric material comprises one or both of silicon oxide and silicon nitride, and/or the second dielectric material comprises silicon oxide.

10. The semiconductor device according to any one of examples 1 to 9, wherein the conductive member comprises polysilicon or a metal or an alloy.

11. The semiconductor device according to any one of examples 1 to 10, wherein the dielectric structure has a substantially uniform thickness on the side wall of the trench.

12. The semiconductor device according to any one of examples 1 to 10, wherein a first thickness of the dielectric material at a first distance from the base of the trench is smaller than a second thickness of the dielectric material at a second distance from the base of the trench, wherein the first distance is greater than the second distance and wherein a first perimeter of the conductive member at the first distance is greater than a second perimeter of the conductive member at the second distance.

13. The semiconductor device according to any one of examples 1 to 10, wherein the side face of the conductive member comprises a step such that an upper portion of the conductive member has an outer width that is greater than an outer width of a lower portion of the conductive member and such that the dielectric material has a first thickness t₁ in a first region of the side wall of the trench and a second thickness t₂ in a second region of the side wall of the trench, wherein t₁≤1.15 t₂ or t₁≤1.2 t₂ or t₁≤1.5 t₂ or t₁≤3 t₂ or t₁≤4 t₂.

14. The semiconductor device according to any one of examples 1 to 13, wherein
the semiconductor substrate is formed of Si, the semiconductor device is a MOSFET and the conductive member provides a field plate, or
the semiconductor substrate is formed of Si, the semiconductor device is a MOSFET and the conductive member provides a gate electrode; or
the semiconductor substrate is formed of SiC, the semiconductor device is a MOSFET and the conductive member provides a gate electrode.

15. The semiconductor device according to any one of examples 1 to 14, wherein the trench is a columnar trench or an elongate trench.

16. A method of forming a conductive member and dielectric structure in a trench, the method comprising:
forming a trench in the first major surface of a semiconductor substrate, the trench having a base and a side wall extending from the base to the first major surface;
forming a first dielectric layer on the side wall and the base of the trench;
forming an electrically conductive layer on the first dielectric material, wherein the electrically conductive layer surrounds a gap in the trench;
selectively removing at least a portion of the conductive layer that is located on the base of the trench and forming a first aperture that exposes the first dielectric material on the base of the trench;
selectively removing a portion of the first dielectric material through the aperture to form a first chamber at the base of the trench.

17. The method of example 16, further comprising: after selectively removing a portion of the first dielectric material through the aperture to form a first chamber at the base of the trench, applying a second dielectric layer onto the first major surface and sealing the gap.

18. The method of example 16 or example 17, wherein after selectively etching a portion of the first dielectric material through the aperture to form a first chamber at the base of the trench, the lower portion of the side wall of the conductive layer is located in the first chamber and the upper portion of the side wall of the conductive layer is attached to the side wall of the trench by the first dielectric layer.

19. The method of any one of examples 16 to 18, wherein the selectively removing a portion of the first dielectric material through the aperture to form a first chamber at the base of the trench comprises wet etching.

20. The method of any one of examples 16 to 19, wherein the selectively etching a portion of the first dielectric material through the aperture to form a first chamber at the base of the trench is performed by anisotropic etching.

21. The method of any one of examples 16 to 20, wherein the selectively etching a portion of the first dielectric material through the aperture to form a first chamber at the base of the trench is performed by isotropic etching.

22. The method of any one of examples 16 to 21, wherein the first dielectric layer is formed by thermal oxidation and/or TEOS deposition.

23. The method of any one of examples 16 to 22, wherein the second dielectric layer is deposited onto the first major surface by PECVD or HDP deposition.

24. The method according to any one of examples 16 to 23, wherein the selectively removing a portion of the first dielectric material through the aperture to form a first chamber at the base of the trench is performed by wet etching and the first chamber is positioned under the conductive member and between a lower portion of the outer surface of the side wall of the conductive member and a lower portion of the side wall of the trench, wherein the first chamber has a height h1, the portion of the side wall of the trench that is in contact with the first dielectric material has a height h2 and the trench has a depth d, wherein d=h1+h2,
wherein the height h1 of the first chamber is adjusted by adjusting the etching time.

25. The method according to any one of examples 16 to 24, wherein the method further comprises a planarization process after applying the first dielectric layer onto the first major surface and sealing the gap.

26. The method according to any one of examples 16 to 25, wherein after forming the electrically conductive layer, the method further comprises:
forming a third dielectric layer on the conductive layer in the trench, wherein the third dielectric layer comprises a thicker upper portion that covers the gap that is surrounded by the conductive layer;
selectively removing the third dielectric layer and forming a second aperture in the thicker upper portion and removing the third dielectric layer from the side wall and base of the conductive layer, and then
selectively removing a portion of the conductive layer located on the base of the trench and forming the first aperture, wherein the second aperture acts as a mask during forming of the first aperture in the conductive layer.

27. The method according to example 26, wherein the third dielectric layer is non-conformally deposited.

28. The method according to example 26 or example 27, wherein the selectively removing the third dielectric layer is performed by anisotropic etching.

29. The method according to any one of examples 16 to 24, wherein after forming the electrically conductive layer, the method further comprises:
forming a fourth dielectric layer over the conductive layer, the fourth dielectric layer filling the trench;
forming a mask on the first major surface that has an opening that exposes the central portion of the fourth dielectric layer located in the trench,
selectively removing the central portion of the dielectric layer and exposing at least a portion of the conductive layer on the base of the trench;
selectively removing a portion of the conductive layer located on the base of the trench and forming the first aperture;
removing the fourth dielectric layer from the trench;
removing the mask.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise. It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate comprising a first major surface;
a trench extending from the first major surface into the semiconductor substrate and having a base and a side wall extending from the base to the first major surface;
a conductive member arranged in the trench and spaced apart from the side wall of the trench by a dielectric structure that is located in the trench, wherein the dielectric structure comprises a first chamber located at the base of the trench,
wherein the conductive member has a side wall having an inner surface and an outer surface, at least a part of the inner surface surrounding a second chamber that is in fluid communication with the first chamber.

2. The semiconductor device of claim 1, wherein the first chamber is positioned under the conductive member and between a lower portion of the outer surface of the side wall of the conductive member and a lower portion of the side wall of the trench.

3. The semiconductor device of claim 1, wherein a lower portion of the side wall of the conductive member protrudes into the first chamber.

4. The semiconductor device of claim 1, wherein the conductive member further comprises a base, and wherein an aperture extends through the base.

5. The semiconductor device of claim 1, wherein the dielectric structure further comprises a first dielectric material extending between an upper portion of the side wall of the trench and an upper portion of the outer surface of the side wall of the conductive member.

6. The semiconductor device of claim 1, wherein the second chamber is covered at the first major surface by a second dielectric material such that the first and second chambers form a cavity within the trench.

7. The semiconductor device of claim 1, wherein the first dielectric material comprises one or both of silicon oxide and silicon nitride, and/or the second dielectric material comprises silicon oxide.

8. The semiconductor device of claim 1, wherein the conductive member comprises polysilicon or a metal or an alloy.

9. The semiconductor device of claim 1, wherein the dielectric structure has a substantially uniform thickness on the side wall of the trench.

10. The semiconductor device of claim 1, wherein a first thickness of the first dielectric material at a first distance from the base of the trench is smaller than a second thickness of the first dielectric material at a second distance from the base of the trench, wherein the first distance is greater than the second distance, and wherein a first perimeter of the conductive member at the first distance is greater than a second perimeter of the conductive member at the second distance.

11. The semiconductor device of claim 1, wherein the side face of the conductive member comprises a step such that an upper portion of the conductive member has an outer width that is greater than an outer width of a lower portion of the conductive member and such that the first dielectric material has a first thickness t₁ in a first region of the side wall of the trench and a second thickness t₂ in a second region of the side wall of the trench, and wherein t₁≤1.15 t₂ or t₁≤1.2 t₂ or t₁≤1.5 t₂ or t₁≤3 t₂ or t₁≤4 t₂.

12. The semiconductor device of claim 1, wherein:
the semiconductor substrate is formed of Si, the semiconductor device is a MOSFET and the conductive member provides a field plate; or
the semiconductor substrate is formed of Si, the semiconductor device is a MOSFET and the conductive member provides a gate electrode; or
the semiconductor substrate is formed of SiC, the semiconductor device is a MOSFET and the conductive member provides a gate electrode.

13. The semiconductor device of claim 1, wherein the trench is a columnar trench or an elongate trench.

14. A method, comprising:
forming a trench in a first major surface of a semiconductor substrate, the trench having a base and a side wall extending from the base to the first major surface;
forming a first dielectric layer on the side wall and the base of the trench;
forming an electrically conductive layer on the first dielectric material, the electrically conductive layer surrounding a gap in the trench;
selectively removing at least a portion of the conductive layer that is located on the base of the trench and forming a first aperture that exposes the first dielectric material on the base of the trench; and
selectively removing a portion of the first dielectric material through the aperture to form a first chamber at the base of the trench.

15. The method of claim 14, further comprising:
after selectively removing a portion of the first dielectric material through the aperture to form the first chamber at the base of the trench, applying a second dielectric layer onto the first major surface and sealing the gap.

16. The method of claim 14, wherein after selectively etching a portion of the first dielectric material through the aperture to form the first chamber at the base of the trench, a lower portion of the side wall of the conductive layer is located in the first chamber and an upper portion of the side wall of the conductive layer is attached to the side wall of the trench by the first dielectric layer.

17. The method of claim 14, wherein the selectively removing a portion of the first dielectric material through the aperture to form a first chamber at the base of the trench comprises wet etching.

18. The method of claim 14, wherein the selectively etching a portion of the first dielectric material through the aperture to form a first chamber at the base of the trench is performed by anisotropic etching.

19. The method of claim 14, wherein the selectively etching a portion of the first dielectric material through the aperture to form a first chamber at the base of the trench is performed by isotropic etching.

20. The method of claim 14, wherein the first dielectric layer is formed by thermal oxidation and/or TEOS deposition.

21. The method of claim 14, wherein the second dielectric layer is deposited onto the first major surface by PECVD or HDP deposition.

22. The method of claim 14, wherein:
the selectively etching a portion of the first dielectric material through the aperture to form the first chamber at the base of the trench is performed by wet etching and the first chamber is positioned under the conductive layer and between a lower portion of the outer surface of the side wall of the conductive layer and a lower portion of the side wall of the trench;
the first chamber has a height h1;
the portion of the side wall of the trench that is in contact with the first dielectric material has a height h2;
the trench has a depth d;
d=h1+h2;
wherein the height h1 of the first chamber is adjusted by adjusting the etching time.

23. The method of claim 14, wherein after forming the electrically conductive layer, the method further comprises:
forming a third dielectric layer on the conductive layer in the trench, the third dielectric layer comprising a thicker upper portion that covers the gap that is surrounded by the conductive layer;
selectively removing the third dielectric layer and forming a second aperture in the thicker upper portion and removing the third dielectric layer from the side wall and a base of the conductive layer; and
then selectively removing a portion of the conductive layer located on the base of the trench and forming the first aperture,
wherein the second aperture acts as a mask during forming of the first aperture in the conductive layer.

24. The method of claim 14, wherein after forming the electrically conductive layer, the method further comprises:
forming a fourth dielectric layer over the conductive layer, the fourth dielectric layer filling the trench;
forming a mask on the first major surface that has an opening that exposes the central portion of the fourth dielectric layer located in the trench;
selectively removing the central portion of the fourth dielectric layer and exposing at least a portion of the conductive layer on the base of the trench;
selectively removing a portion of the conductive layer located on the base of the trench and forming the first aperture;
removing the fourth dielectric layer from the trench; and
removing the mask.
